(19) United States
(12) Patent Application Publication
(10) Pub. No.: US 2025/0149381 A1
(43) Pub. Date: May 8, 2025

(54) GALLIUM INTRODUCTION FOR CAVITY SHAPING ENGINEERING FOR CMOS DEVICES

(71) Applicant: Applied Materials, Inc., Santa Clara, CA (US)

(72) Inventor: Nicolas Louis BREIL, San Jose, CA (US)

(21) Appl. No.: 18/910,704

(22) Filed: Oct. 9, 2024

Related U.S. Application Data
(60) Provisional application No. 63/547,679, filed on Nov. 7, 2023.

(51) Int. Cl. H01L 21/768

(52) U.S. Cl. CPC H01L 21/76877; H01L 21/76816

(57) ABSTRACT

A method of forming an electrical contact in a semiconductor structure includes performing a contact trench forming process to form a contact trench in a dielectric layer formed over a semiconductor region, performing a dopant implanting process to implant dopants in a region of the semiconductor region in proximity to an exposed surface of the semiconductor region within the contact trench, subsequent to the dopant implanting process, performing a cavity shaping process to form a cavity in the exposed surface of the semiconductor region within the contact trench, performing a silicide forming process to form a cavity contact within the contact trench, and performing a metal filling process to form a contact plug in the contact trench.

### CROSS-REFERENCE TO RELATED APPLICATIONS

This application claims priority to U.S. Provisional Application Ser. No. 63/547,679 filed Nov. 7, 2023, which is herein incorporated by reference in its entirety.

### BACKGROUND

### Field

Embodiments described herein generally relate to semiconductor device fabrication, and more particularly, to systems and methods of forming an electrical contact within a semiconductor structure.

### Description of the Related Art

Multi-gate metal-oxide-semiconductor field-effect transistors (MOSFETs), such as complementary metal-oxide semiconductor (CMOS) devices, pose challenges in manufacturability due to their three-dimensional (3D) designs and small sizes. In advanced CMOS devices, metal silicide (e.g., molybdenum silicide (MoSi₂), ruthenium silicide (RuₓSi_{y})) selectively formed at a bottom of a contact trench is often utilized to lower a contact resistivity. However, interfaces of metal silicide at the bottom of a contact trench are often damaged in prior integration steps, such as a dopant implantation process and a contact trench forming etch process, and suffer from low structural and electrical qualities.

Therefore, there is a need for methods and systems that can improve structural and electrical qualities of the interfaces of metal silicide at a bottom of a contact trench.

### SUMMARY

Embodiments of the present disclosure provide a method of forming an electrical contact in a semiconductor structure. The method includes performing a contact trench forming process to form a contact trench in a dielectric layer formed over a semiconductor region, performing a dopant implanting process to implant dopants in a region of the semiconductor region in proximity to an exposed surface of the semiconductor region within the contact trench, subsequent to the dopant implanting process, performing a cavity shaping process to form a cavity in the exposed surface of the semiconductor region within the contact trench, performing a silicide forming process to form a cavity contact within the contact trench, and performing a metal filling process to form a contact plug in the contact trench.

Embodiments of the present disclosure also provide a method of forming an electrical contact in a semiconductor structure. The method includes performing a contact trench forming process to form a contact trench in a dielectric layer formed over a semiconductor region, performing a cavity shaping process to form a cavity in an exposed surface of the semiconductor region within the contact trench, subsequent to the cavity shaping process, performing a dopant implanting process to implant dopants on the exposed surface of the semiconductor region within the contact trench, performing a silicide forming process to form a cavity contact within the contact trench, and performing a metal filling process to form a contact plug in the contact trench.

Embodiments of the present disclosure further provide a method of forming an electrical contact in a semiconductor structure. The method includes forming a cavity in an exposed surface of a semiconductor region exposed by a contact trench in a dielectric layer, by an etch process using chlorine (Cl₂) and hydrogen (H₂).

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic top view of a multi-chamber processing system according to one or more embodiments of the present disclosure.

FIG. 2 depicts a process flow diagram of a method of forming a contact layer in a semiconductor structure according to a first embodiment of the present disclosure.

FIGS. 3A, 3B, 3C, 3D, 3E, and 3F are cross-sectional views of a portion of a semiconductor structure corresponding to various states of the method of FIG. 2.

FIG. 4 depicts a process flow diagram of a method of forming a contact layer in a semiconductor structure according to a second embodiment of the present disclosure.

FIGS. 5A, 5B, 50, 5D, 5E, and 5F are cross-sectional views of a portion of a semiconductor structure corresponding to various states of the method of FIG. 4.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The embodiments described herein provide methods and systems for forming a cavity in a contact trench of a structure that is used to form a CMOS device, to increase a contact interface area, without increasing a critical dimension (CD) of the contact trench, while improving the contact resistivity. The methods include introducing metal dopants, such gallium (Ga), in an area where a cavity is formed by an isotropic etch process using hydrogen (H₂), chlorine (Cl₂), argon (Ar), and helium (He). Since the introduction of metal dopants can slow down an etch rate in certain direction, shape and location of the formed cavity can be engineered depending on the location and the size of a doped region. The location and the size of the doped region can be adjusted by a directional ion implantation process. The introduction of metal dopants, such as gallium (Ga), also reduces the contact resistivity between a semiconductor region and a contact plug within a contact trench.

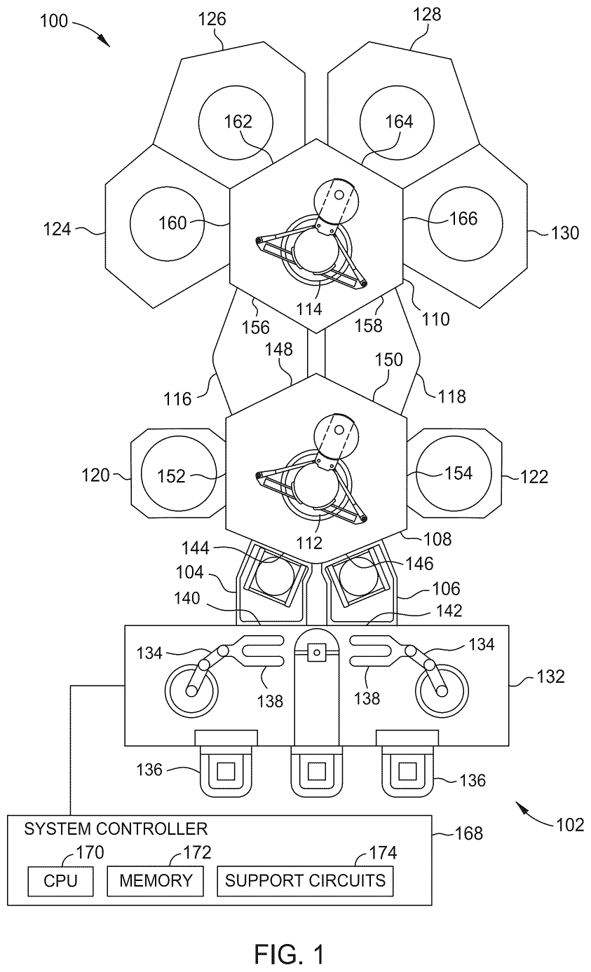

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, the processing chamber 124 can be capable of performing a selective removal process, and the processing chambers 126, 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126, 128, or 130 may be a Centura™ Epi chamber available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

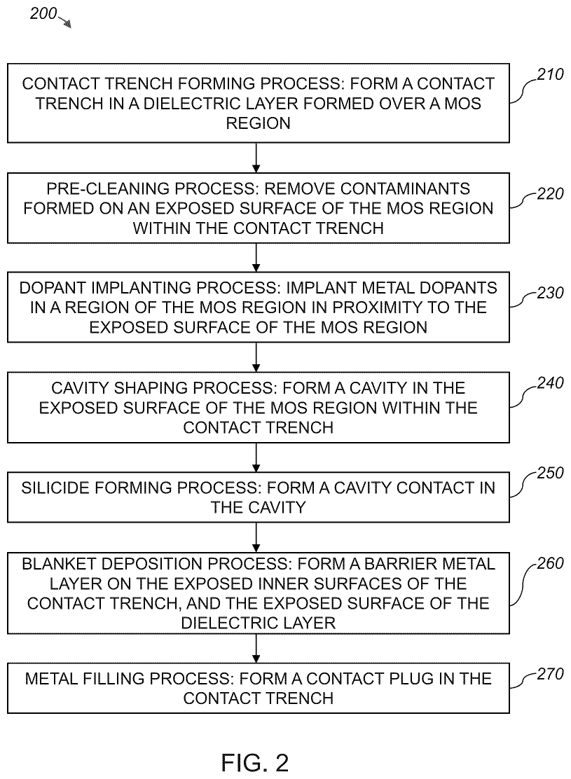

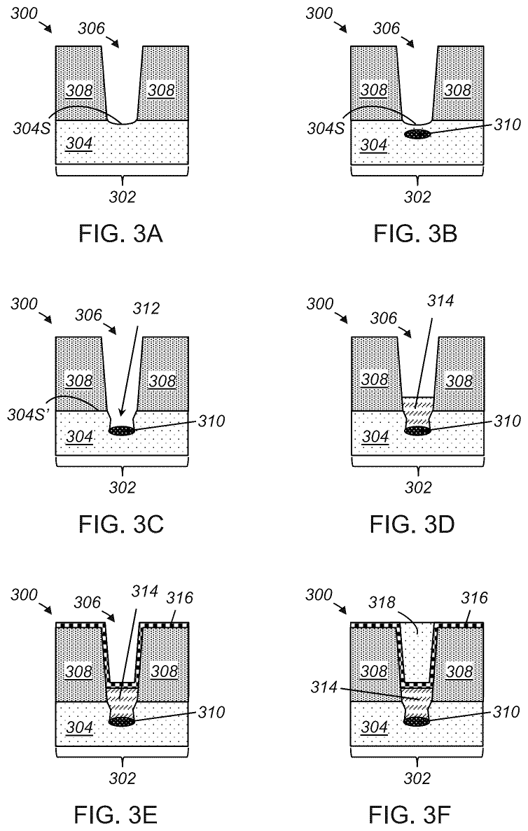

FIG. 2 depicts a process flow diagram of a method 200 of forming a contact layer in a semiconductor structure 300 according to a first embodiment of the present disclosure. FIGS. 3A, 3B, 3C, 3D, 3E, and 3F are cross-sectional views of a portion of the semiconductor structure 300 corresponding to various states of the method 200. It should be understood that FIGS. 3A, 3B, 3C, 3D, 3E, and 3F illustrate only partial schematic views of the semiconductor structure 300, and the semiconductor structure 300 may contain any number of transistor sections and additional materials having aspects as illustrated in the figures. It should also be noted that although the method illustrated in FIG. 2 is described sequentially, other process sequences that include one or more operations that have been omitted and/or added, and/or has been rearranged in another desirable order, fall within the scope of the embodiments of the disclosure provided herein.

Referring to FIGS. 3A, 3B, 3C, 3D, 3E, and 3F, the semiconductor structure 300 may include a portion of a CMOS device 302, which can be an n-type MOS device or a p-type MOS device formed on a substrate (not shown).

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

In some embodiments, the CMOS device 302 is an n-type MOS device of a plurality of n-type transistor devices including a semiconductor region 304 formed of a first material, such as silicon (Si), doped with n-type dopants such as phosphorus (P), antimony (Sb), with the concentration between about 10²⁰ cm⁻³ and 5·×10²¹ cm⁻³.

In some embodiments, the CMOS device 302 is a p-type MOS device of a plurality of p-type transistor devices including a semiconductor region 304 formed of a second material, such as silicon germanium (SiGe), and doped with p-type dopants such as boron (B) or gallium (Ga), with the concentration of between about 10²⁰ cm⁻³ and about 5·×10²¹ cm⁻³.

The first and second materials include materials having differing compositions, such that the second material can be selectively etched relative to the first material (i.e., an etch rate of the second material is higher than an etch rate of the first material). The etch selectivity of the second material (i.e., a ratio of the etch rate of the second material to the etch rate of the first material) is between about 10:1 to 500:1. Other example combinations of the first material and the second material include silicon (Si)/silicon germanium (SiGe), germanium (Ge)/silicon germanium (SiGe), or silicon (Si)/germanium tin (GeSn), respectively.

The semiconductor region 304 may be formed using any suitable deposition technique, such as epitaxial (Epi) deposition, chemical vapor deposition (CVD), atomic layer deposition (ALD), or physical vapor deposition (PVD).

The method 200 begins with block 210, in which a contact trench forming process is performed to form a contact trench 306 in a dielectric layer 308 formed over the semiconductor region 304, as shown in FIG. 3A. The dielectric layer 308 may be formed of a dielectric material, such as silicon dioxide (SiO₂) or silicon nitride (Si₃N₄).

The contact trench forming process in block 210 includes a patterning technique, such as a lithography and an anisotropic remote plasma assisted dry etch process, such as a reactive ion etching (RIE) process, using a plasma formed from a gas including hydrogen (H), argon (Ar), helium (He), or a combination thereof, performed in a processing chamber, such as the processing chamber 122 shown in FIG. 1.

In block 220, a pre-cleaning process is performed to remove contaminants, such as carbon-containing contaminants (e.g., patterning residues), or oxide-containing contaminants (e.g., native oxide layers) formed on an exposed surface 304S of the semiconductor region 304 within the contact trench 306. The pre-cleaning process may be performed in a processing chamber, such as the processing chamber 122 shown in FIG. 1. The pre-cleaning process in block 220 may be performed without breaking vacuum environment in a multi-chamber processing system, such as the multi-chamber processing system 100 shown in FIG. 1.

The pre-cleaning process to remove carbon-containing contaminants may include a RIE process used in the contact trench forming process in block 210. The plasma effluents directionally bombard and remove a remaining dielectric layer within the contact trench 306.

The pre-cleaning process to remove oxide-containing contaminants may include an isotropic plasma etch process, such as a dry chemical etch process, using hydrofluoric acid (HF) and ammonia (NH₃), or a SiCoNi™ dry etch process, using a plasma formed from a gas including ammonia (NH₃), nitrogen trifluoride (NF₃). The dry etch process is selective for oxide layers, and thus does not readily etch silicon, germanium, or nitride layers regardless of whether the layers are amorphous, crystalline or polycrystalline. Selectivity of the dry etch process for oxide versus silicon or germanium is at least about 3:1, and usually 5:1 or better, sometimes 10:1. The dry etch process is also highly selective of oxide versus nitride. The selectivity of the dry etch process versus nitride is at least about 3:1, usually 5:1 or better, sometimes 10:1.

In block 230, a dopant implanting process is performed to implant metal dopants, such as gallium (Ga), in a region 310 of the semiconductor region 304 in proximity to the exposed surface 304S of the semiconductor region 304, as shown in FIG. 3B. The dopant implanting process is performed in a PVD chamber, such as the processing chamber 126, 128, or 130 shown in FIG. 1, by directing ions of metal dopants, such as gallium (Ga), to the exposed surface 304S of the semiconductor region 304 within the contact trench 306. The implanted region 310 may be doped with metal dopants, such as gallium (Ga), with the concentration between about 5×10¹⁹ cm⁻³ and 5×10²¹ cm⁻³, and located at a depth of between about 2 nm and about 10 nm from the surface 304S of the semiconductor region 304. The ion implantation process can be directional and thus the location of the implanted region 310 within the semiconductor region 304 can be adjusted. The dopant implanting process is followed by an anneal process to recrystallize the implanted region 310 of the semiconductor region 304.

The annealing process is performed at a temperature of about 600° C. to about 850° C., for a duration of about 0.1 milliseconds to about 0.5 milliseconds.

In block 240, a cavity shaping process is performed to form a cavity 312 in the exposed surface 304S of the semiconductor region 304 within the contact trench 306, as shown in FIG. 3C. The cavity shaping process may be performed in an etch chamber, such as the processing chamber 120 shown in FIG. 1. The cavity shaping process in block 240 may be performed without breaking vacuum environment in a multi-chamber processing system, such as the multi-chamber processing system 100 shown in FIG. 1.

The cavity shaping process in block 240 includes an isotropic etch process using a chlorine (Cl₂)-based chemistry with additive gas, such as chlorine (Cl₂) and hydrogen (H₂) diluted in argon (Ar) and helium (He).

The cavity shaping process may remove a layer of between about 2 nm and about 3 nm from the surface 304S of the semiconductor region 304, and the resulting cavity 312 may have a width of between about 10 nm and about 30 nm and a depth from an un-etched surface 304S′ of the semiconductor region 304 of between about 2 nm and about 25 nm. The cavity 312 enlarges a contact area between the semiconductor region 304 to a contact plug to be formed within the contact trench 306, to minimize contact resistivity without increasing a critical dimension (CD) of the contact trench 306, leading to an improved device performance. The implanted region 310 doped with metal dopants, such as gallium (Ga), also reduces the contact resistivity between the semiconductor region 304 and the contact plug within the contact trench 306.

The cavity 312 has a shape depending on the location and the size of the implanted region 310. Since an etch rate is lower in the implanted region 310 than the remaining of the semiconductor region 304, the cavity 312 may spread around the implanted region 310. Thus, by adjusting the location and the shape of the cavity 312 in the dopant implanting process in block 230, the shape of the cavity 312 can be adjusted as desired.

The inventors have observed shape modulation of a cavity formed in a semiconductor region in an etch process using chlorine (Cl₂) and hydrogen (H₂) diluted in argon (Ar) and helium (He). Depending on the shape and the location of an implanted region in the semiconductor region, width and depth of a formed cavity were modulated.

The cavity shaping process is also used to refresh (e.g., etching a surface of about a few nanometers that is potentially contaminated with remaining oxygen, nitrogen, or carbon) and prepare pure contamination free exposed surfaces of the cavity 312 on which a contact (e.g., metal silicide) can be formed within the cavity 312 in a subsequent deposition process. The cavity shaping process may also be used to optimize a device stress.

In block 250, a silicide forming process is performed to form a cavity contact 314 in the cavity 312, as shown in FIG. 3D. The cavity contact 314 interfaces with the semiconductor region 304 and a contact plug to be formed within the contact trench 306, and provides an electrical connection therebetween. The silicide forming process includes a deposition process, such as chemical vapor deposition (CVD), physical vapor deposition (PVD), or the like performed in a processing chamber, such as the processing chamber 126, 128, or 130 shown in FIG. 1. The silicide forming process in block 250 may be performed without breaking vacuum environment in a multi-chamber processing system, such as the multi-chamber processing system 100 shown in FIG. 1.

In some embodiments, the cavity contact 314 is formed of a first metal material, such as molybdenum (Mo), ruthenium (Ru), or silicide thereof, on the semiconductor region 304 of p-type. In the deposition process, a deposition gas including a metal source, such as a molybdenum (Mo)-containing halide precursor, or a ruthenium (Ru)-containing organometallic that includes ruthenium (Ru), is used. The silicide forming process may be performed at a temperature of between about 240° C. and about 450° C. and at a pressure of between 3 Torr and 300 Torr. During the deposition process, argon (Ar) gas may be supplied at a flow rate of between about 0 sccm and about 1000 sccm, and hydrogen (H₂) gas may be supplied at a flow rate of between about 500 sccm and about 15000 sccm, for example.

In some embodiments, the cavity contact 314 is formed of a second metal material, such as titanium (Ti), cobalt (Co), nickel (Ni), tantalum (Ta), lanthanum (La), yttrium (Y), hafnium (Hf), zirconium (Zr), or silicide thereof, formed on the semiconductor region 304 of n-type. In the deposition process, a deposition gas including a metal source, such as a precursor containing titanium (Ti), tantalum (Ta), cobalt (Co), nickel (Ni), or a combination thereof. The deposition process may be performed at a temperature of between about 300° C. and about 800° C. and at a pressure of between 1° Torr and 50° Torr.

A cycle of the silicide forming process may be repeated as needed to obtain a desired thickness of the cavity contact 314, for example, between about 5 times and about 1000 times.

In block 260, a blanket deposition process is performed to form a barrier metal layer 316 on the exposed inner surfaces of the contact trench 306, and the exposed surface of the dielectric layer 308, as shown in FIG. 3E. The barrier metal layer 316 protects the cavity contact 314 and allows nucleation and growth of a contact plug in the contact trench 306. The barrier metal layer 316 may be formed of a barrier metal material that is titanium nitride (TiN), or tantalum nitride (TaN). The blanket deposition process in block 260 may be performed without breaking vacuum environment in a multi-chamber processing system, such as the multi-chamber processing system 100 shown in FIG. 1.

In block 270, a metal filling process is performed to form a contact plug 318 in the contact trench 306, as shown in FIG. 3F. The contact plug 318 may be formed of contact plug metal material, such as tungsten (W), cobalt (Co), ruthenium (Ru), or molybdenum (Mo). The contact plug 318 may include a metal that has a desirable work function. The metal filling process in block 270 may include a chemical vapor deposition (CVD) process using a tungsten-containing precursor, such as WF₆, or a cobalt-containing precursor, in a processing chamber, such as the processing chamber 126, 128, or 130 shown in FIG. 1.

After the metal filling process, the semiconductor structure 300 may be planarized, by use of a chemical mechanical planarization (CMP) process.

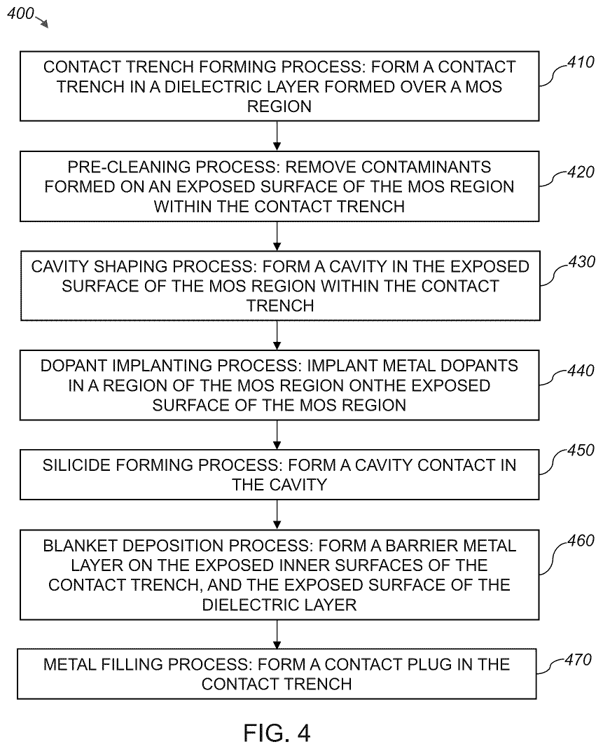

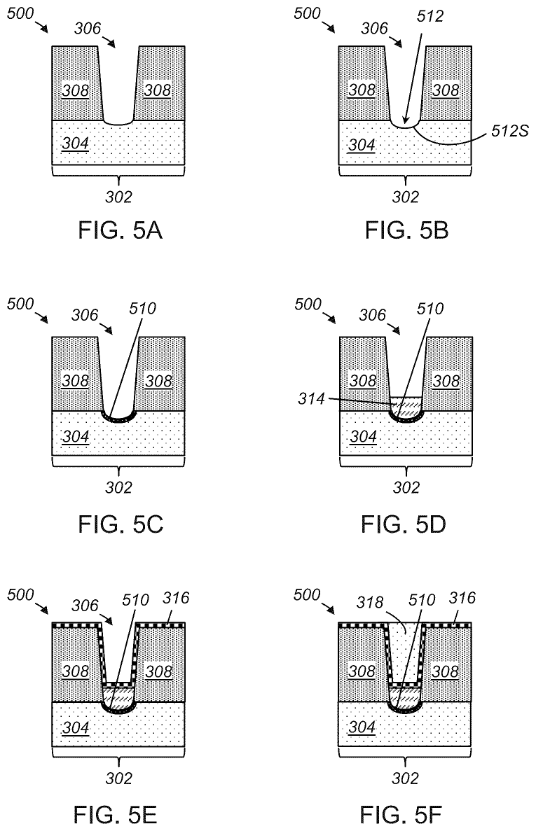

FIG. 4 depicts a process flow diagram of a method 400 of forming a contact layer in a semiconductor structure 500 according to a second embodiment of the present disclosure. In the second embodiment, the order of a cavity shaping process and a dopant implanting process is reversed. The same reference numerals are used for the components that are substantially the same as those of the embodiment, and the description of repeated components may be omitted. FIGS. 5A, 5B, 5C, 5D, 5E, and 5F are cross-sectional views of a portion of the semiconductor structure 500 corresponding to various states of the method 400. It should be understood that FIGS. 5A, 5B, 50, 5D, 5E, and 5F illustrate only partial schematic views of the semiconductor structure 500, and the semiconductor structure 500 may contain any number of transistor sections and additional materials having aspects as illustrated in the figures. It should also be noted that although the method illustrated in FIG. 4 is described sequentially, other process sequences that include one or more operations that have been omitted and/or added, and/or has been rearranged in another desirable order, fall within the scope of the embodiments of the disclosure provided herein.

The method 400 begins with block 410, in which a contact trench forming process is performed to form a contact trench 306 in a dielectric layer 308 formed over the semiconductor region 304, as shown in FIG. 5A. The contact trench forming process in block 410 is similar to or the same as the trench forming process in block 210.

In block 420, a pre-cleaning process is performed to remove contaminants, such as carbon-containing contaminants (e.g., patterning residues), or oxide-containing contaminants (e.g., native oxide layers) formed on the exposed surface of the semiconductor region 304 within the contact trench 306. The pre-cleaning process in block 420 is similar to or the same as the pre-cleaning process in block 220.

In block 430, a cavity shaping process is performed to form a cavity 512 in the exposed surface of the semiconductor region 304 within the contact trench 306, as shown in FIG. 5B. The cavity shaping process in block 430 is similar to or the same as the cavity shaping process in block 240. In the method 400, the dopant implanting process is performed subsequent to the cavity shaping process, and thus in block 430, the cavity 512 is formed in the semiconductor region 304 with no implanted regions formed within. The shape of the cavity 512 is determined by the isotropic etch process.

In block 440, a dopant implanting process is performed to implant metal dopants, such as gallium (Ga), in a region 510 on exposed surfaces 512S of the cavity 512, as shown in FIG. 5C. The dopant implanting process in block 440 is similar to or the same as the dopant implanting process in block 230. The dopant implanting process in block 440 is not followed by a cavity shaping process, which may partially remove the implanted region 510. Thus, improvement of the contact resistivity due to the implanted region 510 doped with metal dopants, such as gallium (Ga), is greater than that of the implanted region 310.

In block 450, a silicide forming process is performed to form a cavity contact 314 in the cavity 512, as shown in FIG. 5D. The silicide forming process in block 450 is similar to or the same as the silicide forming process in block 250.

In block 460, a blanket deposition process is performed to form a barrier metal layer 316 on the exposed inner surfaces of the contact trench 306, and the exposed surface of the dielectric layer 308, as shown in FIG. 5E. The blanket deposition process in block 460 is similar to or the same as the blanket deposition process in block 260.

In block 470, a metal filling process is performed to form a contact plug 318 in the contact trench 306, as shown in FIG. 5F. After the metal filling process, the semiconductor structure 500 may be planarized, by use of a chemical mechanical planarization (CMP) process.

The embodiments described herein provide methods and system for forming an electrical contact. The methods include introducing metal dopants, such gallium (Ga), in an area where a cavity is formed by an isotropic etch process using hydrogen (H₂), chlorine (Cl₂), argon (Ar), and helium (He). Since the introduction of metal dopants can slow down an etch rate in certain direction, shape and location of the formed cavity can be engineered depending on the location and the size of a doped region. The location and the size of the doped region can be adjusted by a directional ion implantation process. The introduction of metal dopants, such as gallium (Ga), also reduces the contact resistivity between a semiconductor region and a contact plug within a contact trench.

While the foregoing is directed to embodiments of the present disclosure, other and further embodiments of the disclosure may be devised without departing from the basic scope thereof, and the scope thereof is determined by the claims that follow.

1. A method of forming an electrical contact in a semiconductor structure, comprising:
performing a contact trench forming process to form a contact trench in a dielectric layer formed over a semiconductor region;
performing a dopant implanting process to implant dopants in a region of the semiconductor region in proximity to an exposed surface of the semiconductor region within the contact trench;
subsequent to the dopant implanting process, performing a cavity shaping process to form a cavity in the exposed surface of the semiconductor region within the contact trench;
performing a silicide forming process to form a cavity contact within the contact trench; and
performing a metal filling process to form a contact plug in the contact trench.

2. The method of claim 1, wherein the semiconductor region comprises silicon doped with n-type dopants or germanium doped with p-type dopants.

3. The method of claim 1, wherein the dopants comprise gallium (Ga).

4. The method of claim 1, wherein:
the cavity shaping process comprises an etch process using chlorine (Cl₂) and hydrogen (H₂), and
the implanted region of the semiconductor region has a lower etch rate than the remaining of the semiconductor region.

5. The method of claim 1, wherein the cavity contact comprises material selected from molybdenum (Mo) silicide, ruthenium (Ru) silicide, and titanium (Ti) silicide.

6. The method of claim 1, further comprising:
prior to the dopant implanting process, performing a pre-cleaning process, comprising:
removing carbon-containing contaminants from the exposed surface of the semiconductor region within the contact trench, by a dry etch process using hydrogen (H) plasma; and
removing oxide-containing contaminants from the exposed surface of the semiconductor region within the contact trench, by a dry etch process.

7. The method of claim 1, the contact plug comprises tungsten (W).

8. The method of claim 1, further comprising:
subsequent to the silicide forming process and prior to the metal filling process, performing a blanket deposition process to form a barrier layer on exposed inner surfaces of the contact trench and on the exposed surface of the dielectric layer.

9. The method of claim 8, wherein the barrier layer comprises titanium nitride (TiN), or tantalum nitride (TaN).

10. A method of forming an electrical contact in a semiconductor structure, comprising:
performing a contact trench forming process to form a contact trench in a dielectric layer formed over a semiconductor region;
performing a cavity shaping process to form a cavity in an exposed surface of the semiconductor region within the contact trench;
subsequent to the cavity shaping process, performing a dopant implanting process to implant dopants on the exposed surface of the semiconductor region within the contact trench;
performing a silicide forming process to form a cavity contact within the contact trench; and
performing a metal filling process to form a contact plug in the contact trench.

11. The method of claim 10, wherein the semiconductor region comprises silicon doped with n-type dopants or germanium doped with p-type dopants.

12. The method of claim 10, wherein the dopants comprise gallium (Ga).

13. The method of claim 10, wherein:
the cavity shaping process comprises an etch process using chlorine (Cl₂) and hydrogen (H₂), and
the implanted region of the semiconductor region has a lower etch rate than the remaining of the semiconductor region.

14. The method of claim 10, wherein the cavity contact comprises material selected from molybdenum (Mo) silicide, ruthenium (Ru) silicide, and titanium (Ti) silicide.

15. The method of claim 10, further comprising:
prior to the dopant implanting process, performing a pre-cleaning process, comprising:
removing carbon-containing contaminants from the exposed surface of the semiconductor region within the contact trench, by a dry etch process using hydrogen (H) plasma; and
removing oxide-containing contaminants from the exposed surface of the semiconductor region within the contact trench, by a dry etch process.

16. The method of claim 10, the contact plug comprises tungsten (W).

17. The method of claim 10, further comprising:
subsequent to the silicide forming process and prior to the metal filling process, performing a blanket deposition process to form a barrier layer on exposed inner surfaces of the contact trench and on the exposed surface of the dielectric layer.

18. The method of claim 17, wherein the barrier layer comprises titanium nitride (TiN), or tantalum nitride (TaN).

19. A method of forming an electrical contact in a semiconductor structure, comprising:
forming a cavity in an exposed surface of a semiconductor region exposed by a contact trench in a dielectric layer, by an etch process using chlorine (Cl₂) and hydrogen (H₂).

20. The method of claim 19, further comprising:
prior to forming the cavity, implanting dopants in a region of the semiconductor region in proximity to the exposed surface of the semiconductor region within the contact trench, wherein the implanted region of the semiconductor region has a lower etch rate than the remaining of the semiconductor region.
